(19) United States
(12) Patent Application Publication
(10) Pub. No.: US 2002/0153946 A1
(43) Pub. Date: Oct. 24, 2002

(54) Dynamic frequency compensated operation amplifier

(76) Inventor: Khiem Quang Nguyen, Tewksbury, MA (US)

Correspondence Address: Iandiorio & Teska, 260 Bear Hill Road, Waltham, MA, 02451-1018, US

(21) Appl. No.: 09/840,557

(22) Filed: Apr. 23, 2001

(51) Int. Cl. H03F 1/02

(52) U.S. Cl. 330/9

(57) ABSTRACT

A dynamic frequency compensated operational amplifier having multiple gain settings includes a first differential to single ended amplifier stage; a second amplifier stage responsive to the first stage; a plurality of compensating capacitors; a multi-gain setting circuit for selectively setting the gain of the operational amplifier; and a control circuit, responsive to the gain set by the multi-gain setting circuit for connecting at least one of the compensating capacitors between the output and the input of the second amplifier stage for adjusting the frequency response of the operational amplifier.

### FIELD OF INVENTION

This invention relates to a dynamic frequency compensated operational amplifier having multiple gain settings.

### BACKGROUND OF INVENTION

Switched capacitor circuits are widely used in implementing data convertors. There are typically two modes in a switched capacitor circuit, namely sampling and integrating modes. In the sampling mode, the input capacitor is connected between the input signal source and the ground. In the integrating mode, the input capacitor is connected between the inverting terminal of the operational amplifier and the ground. Thus the switching of the input capacitor in and out changes the gain of the operational amplifier. It is a characteristic of operational amplifiers that their phase shift varies with their gain and that phase shifts of more than −120° begin to extend the settling time for a sample. As the phase shift grows toward −180° the operational amplifier approaches positive feedback where settling never occurs. Thus settling is an intrinsic problem in switched capacitor circuits. One approach to this is to purposefully, carefully design the circuit so that no matter what the gain, in the two modes the phase shift will always be within the safe phase margin of −60°. One such technique is called pole splitting. But such circuits are relatively large in size and consume substantial power.

### BRIEF SUMMARY OF THE INVENTION

It is therefore an object of this invention to provide an improved frequency compensated operational amplifier.

It is a further object of this invention to provide such an operational amplifier which dynamically adjusts the frequency response as the gain settings change.

It is a further object of this invention to provide such a frequency compensated operational amplifier which maintains a safe phase margin over the range of gain settings.

It is a farther object of this invention to provide such a frequency compensated operational amplifier which has higher speed than a conventional frequency compensated operational amplifier.

It is a further object of this invention to provide such a frequency compensated operational amplifier which has a shorter settling time.

It is a further object of this invention to provide such a frequency compensated operational amplifier which has a higher slew rate.

The invention results from the realization that an improved dynamic, frequency compensated operational amplifier with multiple gain settings, such as occur with switched capacitor networks, having higher speed, shorter settling time and higher slew rate can be achieved by employing a plurality of compensation capacitors, instead of just the single one used in the conventional pole splitting approach to frequency compensation, and switching one or more of those capacitors into and out of the circuit dependent on the particular gain setting in order to adjust the frequency response of the operational amplifier to obtain a predetermined level of phase shift.

This invention features a dynamic frequency compensated operational amplifier having multiple gain settings. There is a first differential to single ended amplifier stage and a second amplifier stage responsive to the first stage. There are a plurality of compensating capacitors and a multi-gain setting circuit for selectively setting the gain of the operational amplifier. A control circuit responsive to the gain set by the multi-gain setting circuit connects at least one of the compensating capacitors between the output and input of the second amplifier stage for adjusting the frequency response of the operational amplifier.

In a preferred embodiment the multi-gain setting circuit may include a switched capacitor network. The switched capacitor network may include an input capacitor and a switching circuit for connecting the input capacitor to sample an input signal in a first mode and deliver that sample to the input of the first amplifier stage in a second mode. The control circuit may interconnect a different compensation capacitor or combination of compensation capacitors to the second amplifier stage in response to each said mode. There may be a reset circuit for connecting the operational amplifier output to its input in a reset mode to obtain unity gain. The control circuit may include a switching apparatus for selectively interconnecting one end of each capacitor to the input and the other end to the output of the second amplifier stage.

### BRIEF DESCRIPTION OF THE DRAWINGS

Other objects, features and advantages will occur to those skilled in the art from the following description of a preferred embodiment and the accompanying drawings, in which:

FIG. 1 is a schematic diagram of a prior art pole-splitting frequency compensation operational amplifier;

FIGS. 2A and 2B illustrate the frequency response of an uncompensated operational amplifier with respect to magnitude and phase shift, respectively;

FIGS. 3A and 3B illustrate the frequency response of an pole-splitting frequency operational prior art amplifier with respect to magnitude and phase shift, respectively;

FIG. 4 is a schematic diagram of a dynamic frequency compensated operational amplifier according to this invention;

FIG. 5 is a truth table showing the operation of the control circuit of FIG. 4;

FIGS. 6A and 6B are frequency responses for the dynamic frequency compensated operational amplifier of FIG. 4 with respect to magnitude and phase shift, respectively; and

FIG. 7 is a more general schematic diagram of a dynamic frequency compensated operational amplifier according to this invention.

### PREFERRED EMBODIMENT

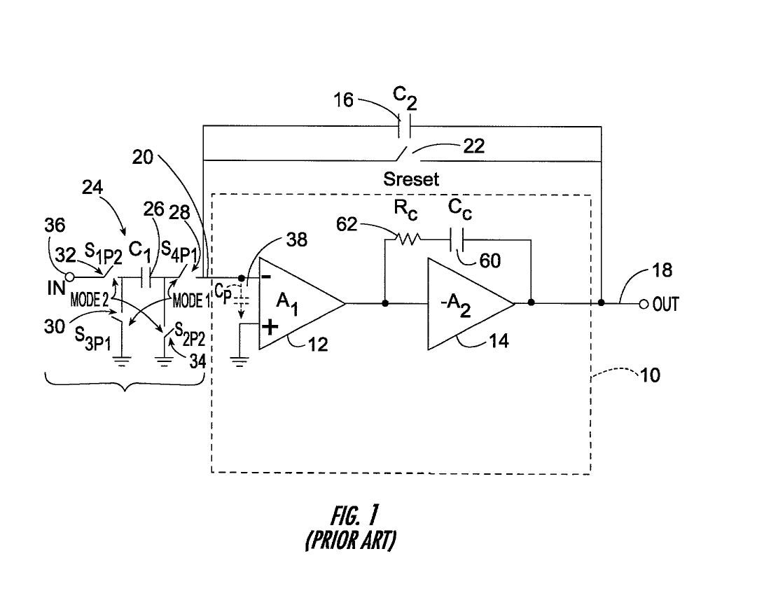

There is shown in FIG. 1, a prior art frequency compensated operational amplifier 10 which uses a pole splitting scheme to compensate for the frequency shift caused by the alternate connection and disconnection of the capacitor in the input network of the operational amplifier. Operational amplifier 10 includes a first differential to single ended amplifier stage 12 and a second stage 14. Feedback capacitor C₂ 16 is interconnected between the output 18 and input 20 of operational amplifier 10. Also connected between the output 18 and input 20 of operational amplifier 10 is reset switch 22 which when closed connects the output 18 to the input 20 of operational amplifier 10 thereby causing it to establish a unity gain condition. A switched capacitor input network 24 includes input capacitor C₁ 26 and four switches 28, 30, 32, and 34.

In operation in mode 2, switches 32 and 34 are closed and switches 28 and 30 are open so that the capacitor C₁ is connected to sample an input signal on input terminal 36. In mode 1 switches 32 and 34 are open and switches 28 and 30 are closed delivering the sample on capacitor 26 to the input of stage 12 of operational amplifier 10. This operation continues so long as there are control signals to switches 28, 30, 32 and 34. The gain of operational amplifier 10 is a function of C₁, C₂ and parasitic capacitance Cₚ38 which is always present: C₁+Cₚ/C₂. Thus, each time switched capacitor input network 24 switches from mode 1 to mode 2 back to mode 1, the gain changes. When the gain changes; the phase shift also changes. That is, the phase of the output signal at output 18 with respect to the input signal at input terminal 36 changes as a function of the change in gain caused by the switching of capacitors in and out of the circuit.

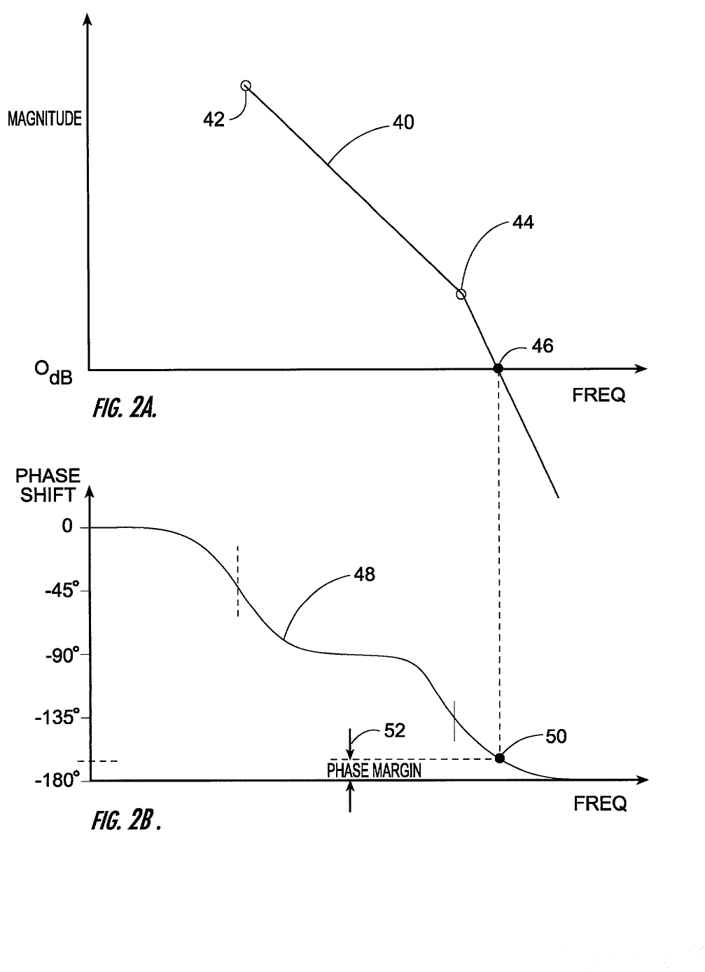

The variation in magnitude and phase shift with respect to frequency for the operational amplifier 10 of FIG. 1 is shown in FIGS. 2A and 2B, respectively. In FIG. 2A it can be seen that the magnitude characteristic 40 is fairly level until it reaches the first pole 42 where it begins a rapid fall off until it reaches second pole 44 where it falls off even more rapidly. At the point 46 where it crosses the 0 dB line, the amplifier produces a unity gain. At this point too, as can be seen from FIG. 2B, the frequency characteristic 48 is approaching −180°. As indicated at point 50, this leaves a very small phase margin 52 which is insufficient; as is well understood in the art a safe phase margin is −60 degrees or more. When the margin becomes less than that, that is, the operational amplifier approaches a 180 degrees phase shift, there is the danger of oscillation and complete breakdown of the operation of the circuit. To prevent this, a phase margin of at least 60 degrees is always sought to be maintained.

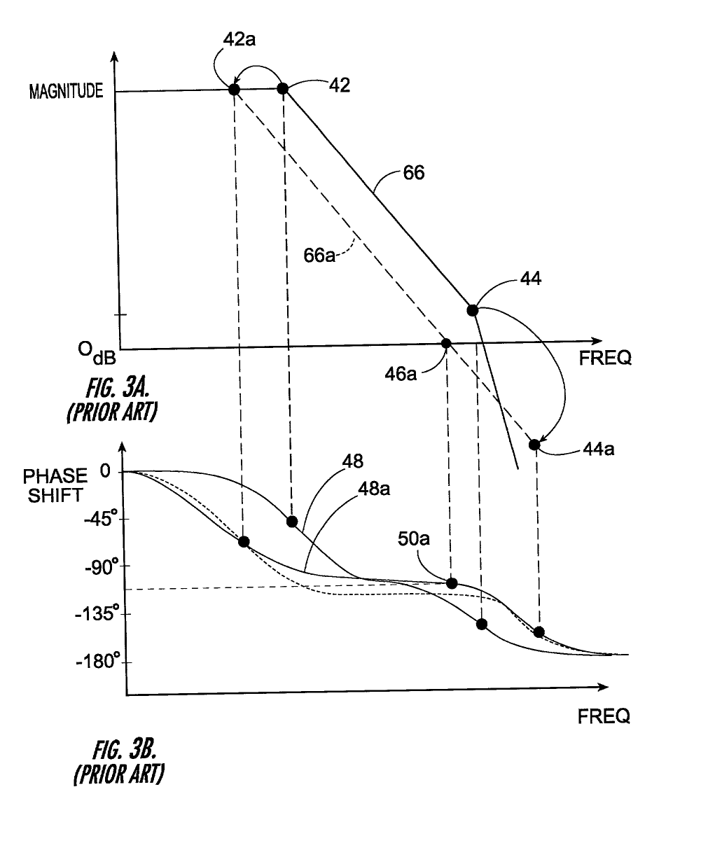

In an attempt to prevent this problem and increase the phase margin to a safe level, the prior art pole splitting technique added a compensation capacitor C_{c} 60 FIG. 1 and also a compensation resistor R_{c} 62 in a feedback loop around the second stage amplifier 14. When that is done, the poles 42 and 44, FIG. 3A, are split or spread to the positions 42a and 44a. This moves the portion 66 of the characteristic between poles 42 and 44 back to the position shown at 66a. In that case, the unity gain point 46a corresponds to the point 50a on characteristic 48a, FIG. 3B, which as can be seen provides a phase shift of approximately −90 degrees which is safely beyond the phase margin of −60 degrees. There are a number of problems with this solution. One is that in order to regain the speed lost by shifting the characteristic from 66 to 66a, one must add substantial power to move the characteristic 66a back out to the level of 66 or beyond. In keeping with this, in order to maintain the phase margin the characteristic 48a must also be shifted out. This requires a substantial increase in size of the capacitance or the silicon. Neither of these are wholly acceptable solutions.

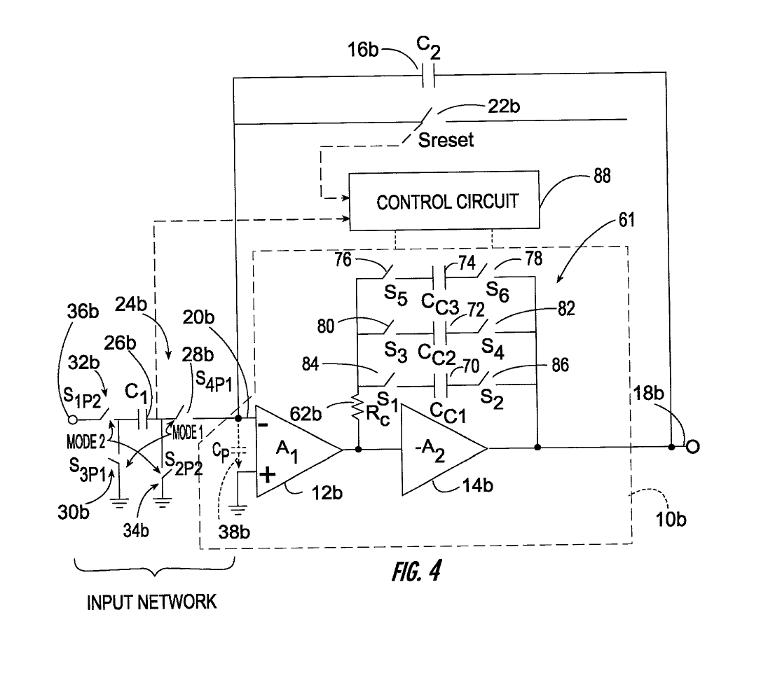

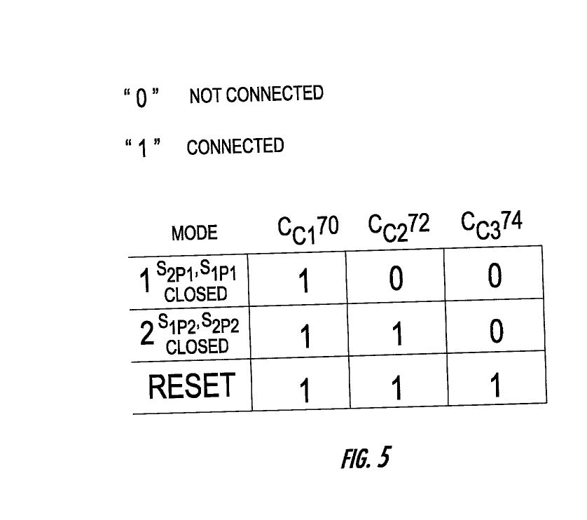

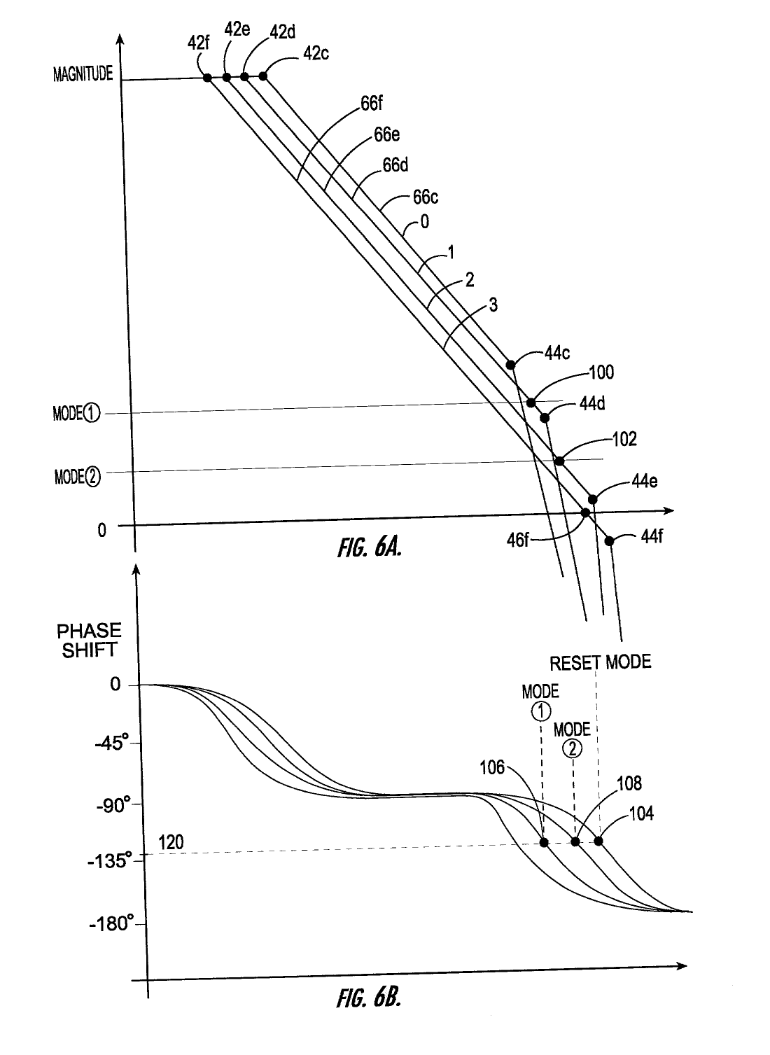

In accordance with this invention, operational amplifier 10b, FIG. 4 includes not one, but a number of compensation capacitors C₁ e.g. C_{c1} 70, C_{c2} 72, and C_{c3} 74 connected in parallel between the input and output of second stage amplifier 14b. Associated with each capacitor 70, 72, and 74 are one or more switches 76, 78, 80, 82, 84, and 86, respectively. A control circuit 88 such as a hard wired logic circuit operates these switches 76-86 to connect a selected one or more of the capacitors 70, 72, and 74 across the second stage amplifier 14b as a function of whether switched capacitor input network 24b is operating in mode 1 or in mode 2 or the system is in a reset mode. In mode 1, switches 28b and 30b are closed, and switches 32b and 34b are open. In mode 2, switches 28b and 30b are open, and switches 32b and 34b are closed. In the reset mode, switch 32b is closed otherwise it is open. The logic implemented in control circuit 88 is shown simply in the truth table of FIG. 5 where mode 1 is shown to have capacitor 70 connected and capacitors 72 and 74 not connected. Mode 2 shows capacitors 70 and 72 connected and capacitor 74 not connected and the reset mode shows all three capacitors 70, 72, and 74 connected. By varying the connection of the capacitors, the phase shift effected by the input capacitor 26b, is compensated for in order to maintain the gain which results in the phase response and phase margin that is desired. For example, as shown in FIG. 6A the characteristic portion 66c may be obtained with no compensation capacitors connected, 66d with only one capacitor connected, 66e with two capacitors connected, and 66f with all three capacitors connected. For providing a number of options it is possible to have mode 1 provide a gain level 100 while in mode 2 the gain level is 102.

Referring now to FIG. 6B illustrating the phase shift characteristic, it can be seen that by projecting those points 100, 102, and 46f the phase shift can be seen at points 104, 106 and 108 all of which result in a phase shift of approximately −120 degrees which is 60 degrees from the −180 degree shift and safely within the −60 degree phase margin.

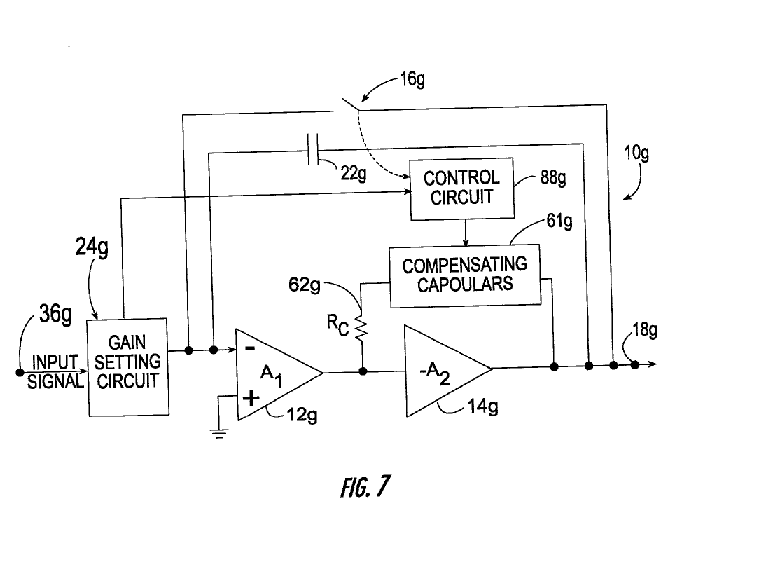

Although thus far the specific embodiment has been shown as operating with a switched capacitor input network as the source of the changes in gain, this is not a necessary limitation of the invention. As shown in FIG. 7 any form e.g., resistors, resistors and capacitors, capacitors of gain setting circuit 24g might be served. So long as the problem arises that with the gain there is a phase shift and with the phase shift comes a need to control the phase response to avoid approaching a 180 degree or positive feedback condition this invention applies and is useful.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

Other embodiments will occur to those skilled in the art and are within the following claims:

What is claimed is:

1. A dynamic frequency compensated operational amplifier having multiple gain settings comprising:
a first differential to single ended amplifier stage;
a second amplifier stage responsive to said first stage;
a plurality of compensating capacitors;
a multi-gain setting circuit for selectively setting the gain of the operational amplifier; and
a control circuit, responsive to the gain set by said multi-gain setting circuit for connecting at least one of said compensating capacitors between the output and input of said second amplifier stage for adjusting the frequency response of the operational amplifier.

2. The dynamic frequency compensated operational amplifier of claim 1 in which said multi-gain setting circuit includes a switched capacitor network.

3. The dynamic frequency compensated operational amplifier of claim 2 in which said switched capacitor network includes an input capacitor and a switching circuit for connecting said input capacitor to sample an input signal in a first mode and deliver that sample to the input of said first amplifier stage in a second mode.

4. The dynamic frequency compensated operational amplifier of claim 3 in which said control circuit interconnects a different compensation capacitor or combination of compensation capacitors to said second amplifier stage in response to each said mode.

5. The dynamic frequency compensated operational amplifier of claim 3 further including a reset circuit for connecting the operational amplifier output to its input in a reset mode to obtain unity gain.

6. The dynamic frequency compensated operational amplifier of claim 1 in which said control circuit includes a switching apparatus for selectively interconnecting one end of each capacitor to the input and the other end to the output of said second amplifier stage.
